(19) United States
(12) Patent Application Publication
(10) Pub. No.: US 2026/0157069 A1
(43) Pub. Date: Jun. 4, 2026

(54) DISPLAY APPARATUS HAVING COLOR FILTERS

(71) Applicant: LG Display Co., Ltd., Seoul (KR)

(72) Inventors: Yeon Suk KANG, Paju-si (KR); Jae Sung LEE, Paju-si (KR); Sae Mi PARK, Paju-si (KR)

(73) Assignee: LG Display Co., Ltd., Seoul (KR)

(21) Appl. No.: 19/317,695

(22) Filed: Sep. 3, 2025

(30) Foreign Application Priority Data
Nov. 29, 2024 (KR) 10-2024-0175298

(51) Int. Cl. H10K 59/38; H10K 59/80; H10K 102/00

(52) U.S. Cl. CPC H10K 59/38; H10K 59/879; H10K 2102/351

(57) ABSTRACT

A display apparatus including color filters is provided. The color filters can be disposed on emission areas of a device substrate. The emission areas can include a first emission area and a second emission area realizing a different color from the first emission area. The color filters can include a first color filter overlapping with the first emission area and a second color filter overlapping with the second emission area. Light emitted from a first light-emitting device disposed between the first emission area and the first color filter can display a same color as light emitted from a second light-emitting device disposed between the second emission area and the second color filter. In the display apparatus, the deviation in the luminance according to a direction in which a viewer at the same viewing angle views an image can be improved, and the overall luminance can be increased.

### CROSS-REFERENCE TO RELATED APPLICATIONS

This application claims priority to Korean Patent Application No. 10-2024-0175298, filed in the Republic of Korea on Nov. 29, 2024, which is hereby expressly incorporated by reference as if fully set forth herein.

### BACKGROUND

### Field

The present disclosure relates to a display apparatus in which color filters are disposed on light-emitting devices.

### Discussion of the Related Art

Generally, a display apparatus provides an image to a user. For example, the display apparatus can include light-emitting devices. Each of the light-emitting devices can display a specific color. For example, each of the light-emitting devices can include a light-emitting unit disposed between a lower electrode and an upper electrode.

The image can be represented in various colors. Light emitted from each light-emitting device can display a same color as light emitted from an adjacent light-emitting device. Further, color filters can be disposed on the light-emitting devices. Each of the color filters can overlap one of the light-emitting devices. For example, the light generated by each light-emitting device can emit through one of the color filters.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of preventing or minimizing the deviation in the luminance according to a location of a viewer at the same viewing angle.

Another object of the present disclosure is to provide a display apparatus capable of increasing the overall luminance of the display apparatus.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. Light-emitting devices are disposed on emission areas of the device substrate. Color filters are disposed on the light-emitting devices. The color filters overlap the emission areas. A filter planarization layer is disposed on the color filters. The filter planarization layer extends beyond each emission area. The color filters include a first color filter and a second color filter. The second color filter is made of a different material from the first color filter. The second color filter includes a central region and a first edge region. The first edge region is disposed between the central region and the first color filter. A thickness of the second color filter gradually changes from the first edge region toward the central region.

According to aspects of the present disclosure, a thickness of the central region can be smaller than a thickness of the first edge region. A thickness of the first color filter is the same as the thickness of the first edge region.

According to aspects of the present disclosure, an upper surface of the second color filter opposite to the device substrate can include a curved region connecting the central region and the first edge region. The curved region can have a concave shape toward a boundary between the first color filter and the second color filter.

According to aspects of the present disclosure, the curved region of the second color filter can be in contact with the filter planarization layer. The filter planarization layer can have a refractive index larger than the second color filter.

According to aspects of the present disclosure, a third color filter can be made of a different material from the first color filter and the second color filter. The second color filter can be disposed between the first color filter and the third color filter. The second color filter can include a second edge region. The second edge region can be disposed between the central region and the third color filter. A thickness of the second color filter can gradually change toward the central region from the second edge region.

According to aspects of the present disclosure, the second edge region can have a shape symmetrical to the first edge region with respect to the central region.

According to aspects of the present disclosure, the first color filter can be a color filter including blue pigment. The second color filter can be a color filter including red pigment. The third color filter can be a color filter including a green pigment.

According to aspects of the present disclosure, the first edge region can include a portion overlapping with the first color filter. The second edge region can include a portion overlapping with the third color filter.

According to aspects of the present disclosure, each of the first color filter, the second color filter and the third color filter can include a lower surface toward the device substrate. A lower surface of the second color filter can be disposed on a same layer as a lower surface of the first color filter and a lower surface of the third color filter. A thickness of the third color filter can be a same as a thickness of the first color filter.

According to aspects of the present disclosure, a thickness of the second edge region can be different from a thickness of the first edge region.

A thickness of each of the first color filter and the third color filter can be greater than or equal to 2.0 μm.

An intermediate insulating layer can be disposed between an upper surface of the second color filter and the filter planarization layer, and the intermediate insulating layer can have a refractive index larger than the second color filter.

An upper surface of the intermediate insulating layer toward the filter planarization layer can be continuous with an upper surface of the first color filter.

An upper surface of the second color filter opposite to the device substrate can include a curved region connecting the central region and the first edge region, the curved region can have a convex shape toward a boundary between the first color filter and the second color filter, and the filter planarization layer contacting the curved region can have a refractive index smaller than the second color filter.

An upper surface of the second color filter can include a first curved surface disposed close to the first color filter and a second curved surface disposed close to the third color filter, and a curvature of the second curved surface can be different from a curvature of the first curved surface.

The display apparatus can further include a collecting lens between the light-emitting device and the second color filter, a surface of the collecting lens toward the filter planarization layer can have a convex shape.

The second color filter can have a refractive index smaller than the collecting lens.

The second color filter can include a lower surface contacting the surface of the collecting lens having a convex shape and an upper surface having a concave shape and contacting the filter planarization layer.

In another embodiment, there is provided a display apparatus comprising a device substrate. The device substrate includes a first emission area and a second emission area. The second emission area realizes a different color from the first emission area. A first light-emitting device is disposed on the first emission area of the device substrate. The first light-emitting device has a stacked structure of a first lower electrode, a first light-emitting unit and a first upper electrode. A second light-emitting device is disposed on the second emission area of the device substrate. The second light-emitting device has a stacked structure of a second lower electrode, a second light-emitting unit and a second upper electrode. Light generated by the second light-emitting unit displays a same color as light generated by the first light-emitting unit. A first color filter is disposed on the first light-emitting device. The first color filter overlaps the first emission area. A second color filter is disposed on the second light-emitting device. The second color filter overlaps the second emission area. A filter planarization layer is disposed on the first color filter and the second color filter. Each of the first color filter and the second color filter includes a lower surface toward the device substrate and an upper surface toward the filter planarization layer. At least one of a lower surface and an upper surface of the second color filter has a concave shape toward a center of the second color filter.

According to aspects of the present disclosure, an upper surface of the first color filter can have a shape parallel to a lower surface of the first color filter.

According to aspects of the present disclosure, a collecting lens can be disposed between the second light-emitting device and the second color filter. The collecting lens can overlap the second emission area. An end portion of the collecting lens can be disposed outside the first emission area. A surface of the collecting lens toward the filter planarization layer can have a convex shape.

According to aspects of the present disclosure, the lower surface of the second color filter can be in contact with the surface of the collecting lens toward the filter planarization layer.

According to aspects of the present disclosure, the second color filter can have a refractive index smaller than the collecting lens.

According to aspects of the present disclosure, the upper surface of the second color filer can be continuous with an upper surface of the first color filter.

According to aspects of the present disclosure, an encapsulation structure can be disposed between the first light-emitting device and the first color filter. The encapsulation structure can extend between the second light-emitting device and the second color filter. A lower surface of the collecting lens and a lower surface of the first color filter, which are toward the device substrate can be in contact with an upper surface of the encapsulation structure toward the filter planarization layer.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to one or more embodiments of the present disclosure;

FIG. 2 is an enlarged view of K1 region in FIG. 1 according to one or more embodiments of the present disclosure;

FIG. 3 is a view showing a circuit of a pixel area in the display apparatus according to the embodiments of the present disclosure;

FIG. 4 is a view taken along I-I′ line of FIG. 2 according to one or more embodiments of the present disclosure;

FIG. 5 is an enlarged view of K2 region in FIG. 4 according to one or more embodiments of the present disclosure;

FIGS. 6 to 8 are graphs showing the luminance of color filters having different thicknesses according to a viewing angle according to one or more embodiments of the present disclosure; and

FIGS. 9 to 13 are views showing the display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the disclosure and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the disclosure of the present disclosure are merely used in order to describe particular embodiments, and are not intended to limit the scope of the present disclosure. For example, an element described in the singular form is intended to include a plurality of elements unless the context clearly indicates otherwise. In addition, in the disclosure of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

Also, unless ‘directly’ is used, the terms “connected” and “coupled” can include that two components are “connected” or “coupled” through one or more other components located between the two components. Further, the term “can” fully encompasses all the meanings and coverages of the term “may” and vice versa.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

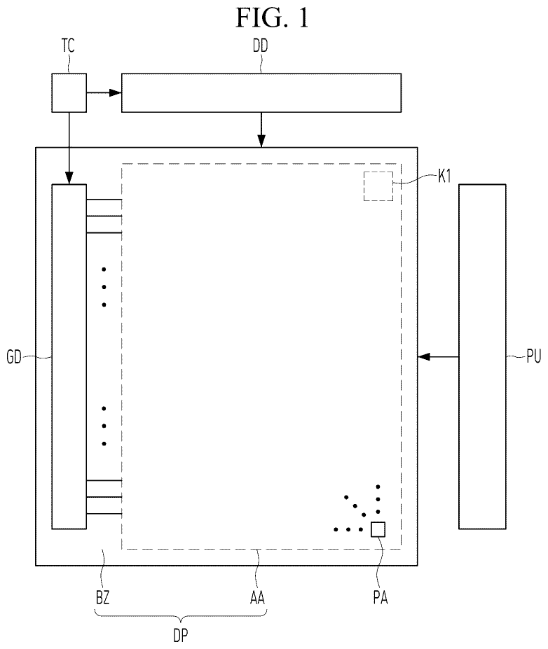

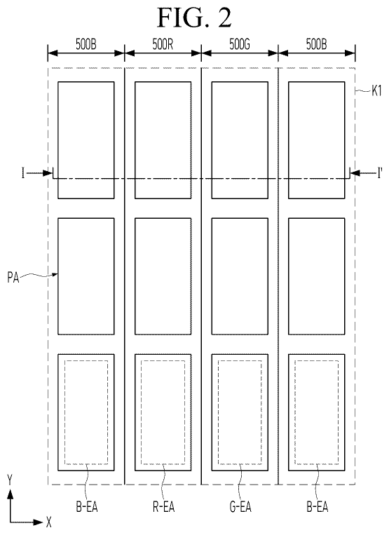

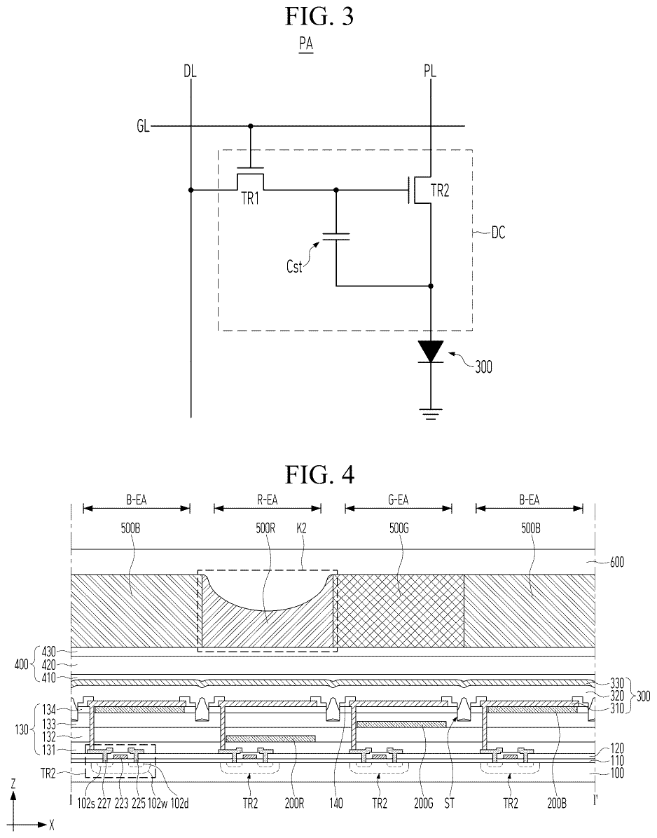

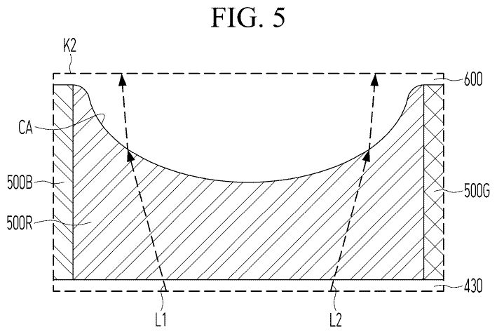

FIG. 1 is a view schematically showing a display apparatus according to embodiments of the present disclosure. FIG. 2 is an enlarged view of K1 region in FIG. 1 according to embodiments of the present disclosure. FIG. 3 is a view showing a circuit of a pixel area in the display apparatus according to the embodiments of the present disclosure. FIG. 4 is a view taken along I-I′ line of FIG. 2 according to embodiments of the present disclosure. FIG. 5 is an enlarged view of K2 region in FIG. 4 according to embodiments of the present disclosure.

Referring to FIGS. 1 to 5, the display apparatus according to the embodiments of the present disclosure can include a display panel DP. The display panel DP can generate an image provided to a user. For example, pixel areas PA can be disposed within the display panel DP. Various signals can be applied to each pixel area PA through signal wirings GL, DL and PL. The signal wirings GL, DL and PL can include a plurality of gate lines GL each applying a gate signal, a plurality of data lines DL each applying a data signal, and a plurality of power voltage supply lines PL supplying a power voltage.

The display panel DP can include an active area AA (or display area) in which the pixel areas PA are disposed and a bezel area BZ disposed outside the active area AA. Each of the signal wirings GL, DL and PL can be electrically connected to the pixel areas PA through the bezel area BZ. For example, the active area AA can be surrounded by the bezel area BZ. A gate driver GD electrically connected to the gate line GL, A data driver DD electrically connected to the data line DL, a power unit PU electrically connected to the power voltage supply line PL, and a timing controller TC controlling the gate driver GD and data driver DD can be disposed outside the active area AA. At least one of the gate driver GD, the data driver DD, the power unit PU and the timing controller TC can be disposed on the bezel area BZ. For example, the display apparatus according to the embodiments of the present disclosure can be a GIP (Gate In Panel) type display apparatus in which the gate driver GD is formed in the bezel area BZ.

Each of the pixel areas PA can realize a specific color. For example, a driving circuit DC electrically connected to the signal wirings GL, DL and PL, and a light-emitting device 300 electrically connected to the driving circuit DC can be disposed in each pixel area PA. The driving circuit DC and the light-emitting device 300 of each pixel area PA can be supported by a device substrate 100. The device substrate 100 can include various materials. For example, the device substrate 100 can be a wafer made of a semiconductor material, such as silicon.

The driving circuit DC can supply a driving current corresponding to the data signal according to the gate signal to the light-emitting device 300 using the power voltage. The driving current supplied to the light-emitting device 300 by the driving circuit DC can be maintained for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first well region, a first drain region, a first source region, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal using the power voltage. For example, the second thin film transistor TR2 can function as a driving thin film transistor. The second thin film transistor TR2 can include a second well region 102w, a second drain region 102d, a second source region 102s, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second well region 102w, the second drain region 102d and the second source region 102s can be formed in the device substrate 100. Each of the second well region 102w, the second drain region 102d and the second source region 102s can include a conductive impurity. For example, the process of forming the second well region 102w, the second drain region 102d and the second source region 102s can be including a process of doping a portion of the device substrate 100 with a conductive impurity. The second drain region 102d and the second source region 102s can include a conductive impurity having a different type from the second well region 102w. For example, the second well region 102w can include an n-type impurity, and the second drain region 102d and the second source region 120s can include a p-type impurity. The second drain region 102d and the second source region 102s can be disposed within the second well region 102w.

The second well region 102w can include a conductive impurity having a different type from the first well region. The second drain region 102d and the second source region 102s can include a conductive impurity having a different type from the first drain region and the first source region. For example, the second well region 102w can include a conductive impurity having a same type as the first drain region and the first source region, and the second drain region 102d and the second source region 102s can include a conductive impurity having a same type as the first well region. Thus, in the display apparatus according to the embodiments of the present disclosure, the second thin film transistor TR2 can have characteristics different from the first thin film transistor TR1. The second well region 102w can be formed simultaneously with the first drain region and the first source region, and the second drain region 102d and the second source region 102s can be formed simultaneously with the first well region. Therefore, in the display apparatus according to the embodiments of the present disclosure, the process efficiency can be improved.

The second gate electrode 223 can be disposed on the device substrate 100. For example, the second gate electrode 223 can overlap a portion of the second well region 102. The second gate electrode 223 can include a conductive material. For example, the second gate electrode 223 can include a metal, such as aluminum (Al), chromium (Cr), copper (Cu), molybdenum (Mo), titanium (Ti) and tungsten (W). A portion of the second well region 102w overlapping with the second gate electrode 223 can be disposed between the second drain region 102d and the second source region 102s. The second gate electrode 223 can be spaced apart from the device substrate 100. The second gate electrode 223 can be insulated from the device substrate 100. For example, a portion of the second well region 102w overlapping with the second gate electrode 223 between the second drain region 102d and the second source region 102s can have an electrical conductivity corresponding to a voltage of a signal applied to the second gate electrode 223. For example, in the display apparatus according to the embodiments of the present disclosure, a portion of the second well region 102w overlapping with the second gate electrode 223 between the second drain region 102d and the second source region 102s can function as a channel region of the second thin film transistor TR2.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be disposed on the device substrate 100. The second drain electrode 225 can be electrically connected to the second drain region 102d. The second drain electrode 225 can include a conductive material. For example, the second drain electrode 225 can include a metal, such as aluminum (Al), chromium (Cr), copper (Cu), molybdenum (Mo), titanium (Ti) and tungsten (W). The second drain electrode 225 can be spaced apart from the device substrate 100. The second drain electrode 225 can be insulated from the second gate electrode 223. For example, the second drain electrode 225 can be disposed on a different layer from the second gate electrode 223. The second drain electrode 225 can include a different material from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be disposed on the device substrate 100. The second source electrode 227 can be electrically connected to the second source region 102s. The second source electrode 227 can include a conductive material. For example, the second source electrode 227 can include a metal, such as aluminum (Al), chromium (Cr), copper (Cu), molybdenum (Mo), titanium (Ti) and tungsten (W). The second source electrode 227 can be spaced apart from the device substrate 100. The second source electrode 227 can be insulated from the second gate electrode 223. For example, the second source electrode 227 can be disposed on a different layer from the second gate electrode 223. The second source electrode 227 can include a different material from the second gate electrode 223.

The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of the signal applied to the second gate electrode 223 for one frame. The storage capacitor Cst can have a stacked structure of capacitor electrodes. For example, the storage capacitor Cst can have a stacked structure of a first capacitor electrode electrically connected to the second gate electrode 223 and a second capacitor electrode electrically connected to the second source electrode 227. The storage capacitor Cst can be formed by using a process of forming the first thin film transistor TR1 and the second thin film transistor TR2. For example, the first capacitor electrode can be formed simultaneously with the second gate electrode 223, and the second capacitor electrode can be formed simultaneously with the second source electrode 227. Thus, in the display apparatus according to the embodiments of the present disclosure, the process efficiency can be improved.

At least one insulating layer 110, 120, 130 and 140 for preventing unnecessary electrical connection can be disposed on the device substrate 100. For example, a gate insulating layer 110, an interlayer insulating layer 120, a device planarization layer 130 and fences 140 can be disposed on the device substrate 100.

The gate insulating layer 110 can be disposed close to the device substrate 100. The second gate electrode 223 of each pixel area PA can be insulated from the device substrate 100 by the gate insulating layer 120. For example, the first gate electrode and the second gate electrode 223 of each pixel area PA can be disposed on the gate insulating layer 120 completely covering an upper surface of the device substrate 100. The gate insulating layer 110 can include an insulating material. For example, the gate insulating layer 110 can be an inorganic insulating layer made of an inorganic insulating material, such as silicon oxide (SiOx) and silicon nitride (SiNx). The second gate electrode 223 of each pixel area PA can have a same level as the first gate electrode of each pixel area PA. For example, a distance between the device substrate 100 and the second gate electrode 223 of each pixel area PA can be a same as a distance between the device substrate 100 and the first gate electrode of each pixel area PA. The gate insulating layer 110 can be a linear insulating layer having a constant thickness.

The interlayer insulating layer 120 can be disposed on the gate insulating layer 110. The second drain electrode 225 and the second source electrode 227 of each pixel area PA can be insulated from the second gate electrode 223 of the corresponding pixel area PA by the interlayer insulating layer 120. For example, the interlayer insulating layer 120 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 120. The interlayer insulating layer 120 can include an insulating material. For example, the interlayer insulating layer 120 can be an inorganic insulating layer made of an inorganic insulating material.

The device planarization layer 130 can be disposed on the interlayer insulating layer 120. The device planarization layer 130 can remove a thickness difference due to the driving circuit DC of each pixel area PA. For example, the first drain electrode, the first source electrode, the second drain electrode 225 and the second source electrode 227 of each pixel area PA can be covered by the device planarization layer 130. An upper surface of the device planarization layer 130 opposite to the device substrate 100 can be flat. For example, the upper surface of the device planarization layer 130 can be parallel to the upper surface of the device substrate 100. The device planarization layer 130 can include an insulating material. The device planarization layer 130 can include a material having a high fluidity. For example, the device planarization layer 130 can be an organic insulating layer made of an organic insulating material.

The light-emitting device 300 of each pixel area PA can be disposed on the device planarization layer 130. The light-emitting device 300 of each pixel area PA can emit light displaying a specific color. For example, the light-emitting device 300 of each pixel area PA can include a lower electrode 310, a light-emitting unit 320 and an upper electrode 330, which are sequentially stacked on the device planarization layer 130.

The lower electrode 310 and the upper electrode 330 can include a conductive material. The upper electrode 330 can include a different material from the lower electrode 310. For example, the lower electrode 310 can be a transparent electrode made of a transparent conductive material, such as ITO and IZO, and the upper electrode can be a translucent electrode in which a metal, such as silver (Ag) and magnesium(Mg) is thinly formed. The upper electrode 330 can have a work-function different from the lower electrode 310. For example, a work-function of the upper electrode 330 can be smaller than a work-function of the lower electrode 310. Thus, in the display apparatus according to the embodiments of the present disclosure, the lower electrode 310 can function as an anode, and the upper electrode 330 can function as a cathode.

The light-emitting unit 320 can generate light having luminance corresponding to a voltage difference between the lower electrode 310 and the upper electrode 330. For example, the light-emitting unit 320 can include an emission material layer (EML). The emission material layer can include an organic emission material, an inorganic emission material or a hybrid emission material. For example, the display apparatus according to the embodiments of the present disclosure can be an organic light emitting display apparatus including an organic emission material.

The light-emitting unit 320 can have a multi-layer structure. For example, the light-emitting unit 320 can further include at least one of a hole injection layer (HIL), a hole transport layer (HTL), an electron transport layer (ETL) and an electron injection layer (EIL). Thus, in the display apparatus according to the embodiments of the present disclosure, the efficiency of the light-emitting unit 320 can be improved.

The fences 140 can be disposed on the device planarization layer 130. The fences 140 can include an insulating material. Each of the fences 140 can have a constant thickness. For example, the fences 140 can be an inorganic insulating layer made of an inorganic insulating material. The fences 140 can define an emission area R-EA, G-EA and B-EA in each pixel area PA. The emission area R-EA, G-EA and B-EA of each pixel area PA can mean an area where light is generated. For example, the light-emitting unit 320 can be in direct contact with the lower electrode 310 and the upper electrode 330 within the emission area R-EA, G-EA and B-EA of each pixel area PA.

The lower electrode 310 of each pixel area PA can be spaced apart from the lower electrode 301 of adjacent pixel area PA. The lower electrode 310 of each pixel area PA can be insulated from the lower electrode 310 of adjacent pixel area PA by the fences 140. For example, an edge of the lower electrode 310 in each pixel area PA can be covered by the fences 140. A portion of the lower electrode 310 overlapping with the emission area R-EA, G-EA and B-EA of each pixel area PA can be in direct contact with the upper surface of the device planarization layer 130.

The driving current generated by the driving circuit DC of each pixel area PA can be applied to the lower electrode 310 of the corresponding pixel area PA. For example, the lower electrode 310 of each pixel area PA can be in direct contact with the second source electrode 227 of the corresponding pixel area PA by penetrating the device planarization layer 130. A connection point between the lower electrode 310 and the second source electrode 227 in each pixel area PA can be disposed outside the emission area R-EA, G-EA and B-EA defined in the corresponding pixel area PA. For example, the connection point between the lower electrode 310 and the second source electrode 227 in each pixel area PA can overlap one of the fences 140. Thus, in the display apparatus according to the embodiments of the present disclosure, the deviation in the luminance of the light emitted from the emission area R-EA, G-EA and B-EA of each pixel area PA due to the difference in the location can be prevented.

Light generated from the light-emitting unit 320 of each pixel area PA can display a same color as light generated by the light-emitting unit 320 of adjacent pixel area PA. For example, the light generated by the light-emitting unit 320 of each pixel area PA can display a white color. The light-emitting unit 320 of each pixel area PA can have a stacked structure same as the light-emitting unit 320 of adjacent pixel area PA. The light-emitting unit 320 of each pixel area PA can be formed simultaneously with the light-emitting unit 320 of adjacent pixel area PA.

A signal applied to the upper electrode 330 of each pixel area PA can be the same as a signal applied to the upper electrode 330 of adjacent pixel area PA. For example, the upper electrode 330 of each pixel area PA can be electrically connected to the upper electrode 330 of adjacent pixel area PA. The upper electrode 330 of each pixel area PA can include a same material as the upper electrode 330 of adjacent pixel area PA. The upper electrode 330 of each pixel area PA can be formed by a same process as the upper electrode of adjacent pixel area PA. For example, the upper electrode 330 of each pixel area PA can be formed simultaneously with the upper electrode 330 of adjacent pixel area PA. The upper electrode 330 of each pixel area PA can be in direct contact with the upper electrode 330 of adjacent pixel area PA. Thus, in the display apparatus according to the embodiments of the present disclosure, a process of forming the upper electrode 330 of each pixel area PA can be simplified.

The image provided to the user can include various colors by the light emitted from the emission areas R-EA, G-EA and B-EA of the pixel areas PA. For example, the emission area R-EA, G-EA and B-EA of each pixel area PA can be one of a red emission area R-EA emitting red light displaying a red color, a green emission area G-EA emitting green light displaying a green color, and a blue emission area B-EA emitting blue light displaying a blue color. A micro-cavity structure can be formed in the emission area R-EA, G-EA and B-EA of each pixel area PA. For example, a reflective electrode 200R, 200G and 200B can be disposed between the driving circuit DC and the lower electrode 310 of each pixel area PA. Thus, in the display apparatus according to the embodiments of the present disclosure, some of the light generated by the light-emitting unit 320 of each pixel area PA having a wavelength range corresponding to a color realized by the emission area R-EA, G-EA and B-EA of the corresponding pixel area PA can be amplified between the reflective electrode 200R, 200G and 200B and the upper electrode 330 of the corresponding pixel area PA. For example, in the display apparatus according to the embodiments of the present disclosure, the red light can be amplified between a red reflective electrode 200R and the upper electrode 330 of the red emission area R-EA, the green light can be amplified between a green reflective electrode 200G and the upper electrode 330 of the green emission area G-EA, and the blue light can be amplified between a blue reflective electrode 200B and the upper electrode 330 of the blue emission area B-EA. The light amplified between the reflective electrode 200R, 200G and 200B and the upper electrode 300 of each pixel area PA can be emitted through the upper electrode 330 of the corresponding pixel area PA.

The location of the reflective electrode 200R, 200G and 200B in the emission area R-EA, G-EA and B-EA of each pixel area PA can be different according to a color realized by the emission area R-EA, G-EA and B-EA of the corresponding pixel area PA. For example, the green reflective electrode 200G can be disposed on a different layer from the red reflective electrode 200R, and the blue reflective electrode 200B can be disposed on a different layer from the green reflective electrode 200G and the red reflective electrode 200R. The wavelength range of the light amplified between the reflective electrode 200R, 200G and 200B and the upper electrode 330 of each pixel area PA can be determined by a distance between the reflective electrode 200R, 200G and 200B and the upper electrode 330 of the corresponding pixel area PA. For example, the device planarization layer 130 can include a first planarization layer 131, a second planarization layer 132, a third planarization layer 133 and a fourth planarization layer 134, which are sequentially stacked, the red reflective electrode 200R in the red emission area R-EA can be disposed between the first planarization layer 131 and the second planarization layer 132, the green reflective electrode 200G in the green emission area G-EA can be disposed between the second planarization layer 132 and the third planarization layer 133, and the blue reflective electrode 200B in the blue emission area B-EA can be disposed on the third planarization layer 133.

An upper surface of the blue reflective electrode 200B opposite to the device substrate 100 can be in direct contact with the lower electrode 310 of the blue emission area B-EA. For example, a thickness of the blue reflective electrode 200B can be a same as a thickness of the fourth planarization layer 134. The lower electrode 310 of each pixel area PA can include a region being in contact with an upper surface of the fourth planarization layer 134 opposite to the device substrate 100. For example, a side surface of the blue reflective electrode 200B can be surrounded by the fourth planarization layer 134. Thus, in the display apparatus according to the embodiments of the present disclosure, the overall thickness can be decreased.

A region disposed between the emission areas R-EA, G-EA and B-EA can be defined as a non-emission area. For example, the fences 140 can be disposed in the non-emission area. A separating trench ST can be disposed within the non-emission area disposed between the fences 140. The separating trench ST can be formed in the device planarization layer 130. The separating trench ST can be disposed close to the upper surface of the device planarization layer 130. For example, the separating trench ST can have a groove shape in which a portion of the device planarization layer 130 is removed. The separating trench ST can be surrounded by the device planarization layer 130. An air-gap can be formed inside the separating trench ST. The light-emitting unit 320 of each pixel area PA can be partially separated from the light-emitting unit 320 of adjacent pixel area PA by the fences 140 and the separating trench ST. For example, the light-emitting unit 320 of each pixel area PA can include emission stacks and at least one charge generating layer between the emission stacks, and the charge generating layer on each pixel area PA can be separated from the charge generating layer of adjacent pixel area PA by the fences 140 and the separating trench ST. Thus, in the display apparatus according to the embodiments of the present disclosure, the leakage of the driving current applied to the pixel area PA through the charge generating layer can be prevented. Therefore, in the display apparatus according to the embodiments of the present disclosure, the malfunction of the light-emitting device 300 in each pixel area PA due to the leakage current can be prevented.

An encapsulation structure 400 can be disposed on the light-emitting device 300 of each pixel area PA. The encapsulation structure 400 can prevent the damage of the light-emitting device 300 in each pixel area PA due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked on the upper electrode 330. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can be an inorganic encapsulating layer made of an inorganic insulating material, and the second encapsulating layer 420 can be an organic encapsulating layer made of an organic insulating material. Thus, in the display apparatus according to the embodiments of the present disclosure, a thickness difference due to the light-emitting device 300 of each pixel area PA can be removed by the second encapsulating layer 420. For example, an upper surface of the third encapsulating layer 430 opposite to the device substrate 100 can be flat.

Color filters 500R, 500G and 500B can be disposed on the encapsulation structure 400. The color filter 500R, 500G and 500B can overlap the emission areas R-EA, G-EA and B-EA of the pixel areas PA. For example, the light emitted from the light-emitting device 300 of each pixel area PA can pass through one of the color filters 500R, 500G and 500B. The light passing through the color filter 500R, 500G and 500B disposed on each pixel area PA can display a same color as the light emitted from the emission area R-EA, G-EA and B-EA of the corresponding pixel area PA. For example, the color filters 500R, 500G and 500B can include a red color filter 500R overlapping with the red emission area R-EA, a green color filter 500G overlapping with the green emission area G-EA, and a blue color filter 500B overlapping with the blue emission area B-EA. Thus, in the display apparatus according to the embodiments of the present disclosure, the color reproduction can be improved. The color filters 500R, 500G and 500B can be formed of various materials. For example, each of the color filters 500R, 500G and 500B can include a pigment. Therefore, in the display apparatus according to the embodiments of the present, the reliability at high temperatures can be improved.

The color filters 500R, 500G and 500B can be disposed side by side. For example, a lower surface of each color filter 500R, 500G and 500B toward the device substrate 100 can be in direct contact with the upper surface of the encapsulation structure 400. A side surface of each color filter 500R, 500G and 500B can be in direct contact with adjacent color filter 500R, 500G and 500B. For example, a boundary of adjacent color filters 500R, 500G and 500B can overlap the separating trench ST. Thus, in the display apparatus according to the embodiments of the present disclosure, the deterioration in the quality of the image recognized by the user due to the light that does not pass through the color filters 500R, 500G and 500B can be prevented. For example, in the display apparatus according to the embodiments of the present, the light leakage can be prevented.

The pixel areas PA can be disposed side by side in a first direction X and a second direction Y perpendicular to the first direction X. For example, the pixel areas PA can be arranged in a matrix form. The emission area R-EA, G-EA and B-EA of each pixel area PA can display a different color from the emission area R-EA, G-EA and B-EA of the pixel area PA adjacent in the first direction X. For example, in the display apparatus according to the embodiments of the present disclosure, the red emission area R-EA, the green emission area G-EA and the blue emission area B-EA can be repeatedly arranged in the first direction X. The emission area R-EA, G-EA and B-EA of each pixel area PA can display a same color as the emission area R-EA, G-EA and B-EA of the pixel area PA adjacent in the second direction Y. For example, each of the color filter 500R, 500G and 500B can extend in the second direction Y. The display apparatus according to one or more embodiments of the present disclosure can be a stripe-type display apparatus in which the color filters 500R, 500G and 500B extending in the second direction Y can be disposed side by side in the first direction X.

A filter planarization layer 600 can be disposed on the color filters 500R, 500G and 500B. The filter planarization layer 600 can prevent the damage of the color filters 500R, 500G and 500B due to the external impact. The filter planarization layer 600 can include an insulating material. For example, the filter planarization layer 600 can include an inorganic insulating material and/or an organic insulating material. A thickness difference due to the color filters 500R, 500G and 500B can be removed by the filter planarization layer 600. For example, an upper surface of the filter planarization layer 600 opposite to the device substrate 100 can be flat. Thus, in the display apparatus according to the embodiments of the present disclosure, the occurrence of spots due to the difference in a level between the upper surface of the color filters 500R, 500G and 500B can be prevented.

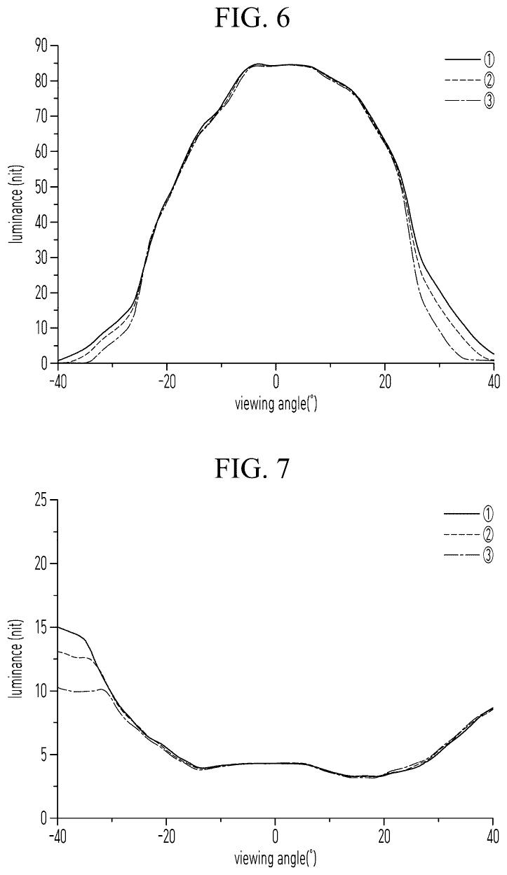

FIG. 6 is a graph showing the luminance of a first green color filter \textcircled{1} having a thicknesses of 1.3 [symbol] , a second green color filter \textcircled{2} having a thicknesses of 1.5 [symbol] and a third green color filter \textcircled{3} having a thicknesses of 2.0 [symbol] according to a viewing angle. FIG. 7 is a graph showing the luminance of a first blue color filter \textcircled{1} having a thicknesses of 1.3 [symbol] , a second blue color filter \textcircled{2} having a thicknesses of 1.5 [symbol] and a third blue color filter \textcircled{3} having a thicknesses of 2.0 [symbol] according to a viewing angle. Herein, the first green color filter, the second green color filter and the third green color filter include a green pigment, and the first blue color filter, a second blue color filter and a third blue color filter include a blue pigment.

Referring to FIGS. 6 and 7, light passing through the green color filters including a green pigment and light passing through the blue color filters including a blue pigment can have different luminance according to a viewing angle of viewers having a same viewing angle. For example, a green color and a blue color recognized by a viewer having a viewing angle of 30° to 40° to the right from the front can have different luminance from a green color and a blue color recognized by a viewer having a viewing angle of 30° to 40° to the left from the front. The asymmetry in the luminance of the green color and the blue color depending on a viewing direction can be reduced as a thickness of the green color filter having a green pigment and a thickness of the blue color filter having a blue pigment increase. Thus, in the display apparatus according to the embodiments of the present disclosure, the thickness of the green color filter 500G overlapping with the green emission area G-EA and the thickness of the blue color filer 500B overlapping with the blue emission area B-EA can be increased. For example, in the display apparatus according to the embodiments of the present disclosure, the thickness of the green color filter 500G and the thickness of the blue color filter 500B can be greater than or equal to 2.0 [symbol] . Therefore, in the display apparatus according to the embodiments of the present disclosure, the asymmetry in the luminance depending on a viewing direction due to the green color filter 500G and the blue color filter 500B can be prevented or minimized.

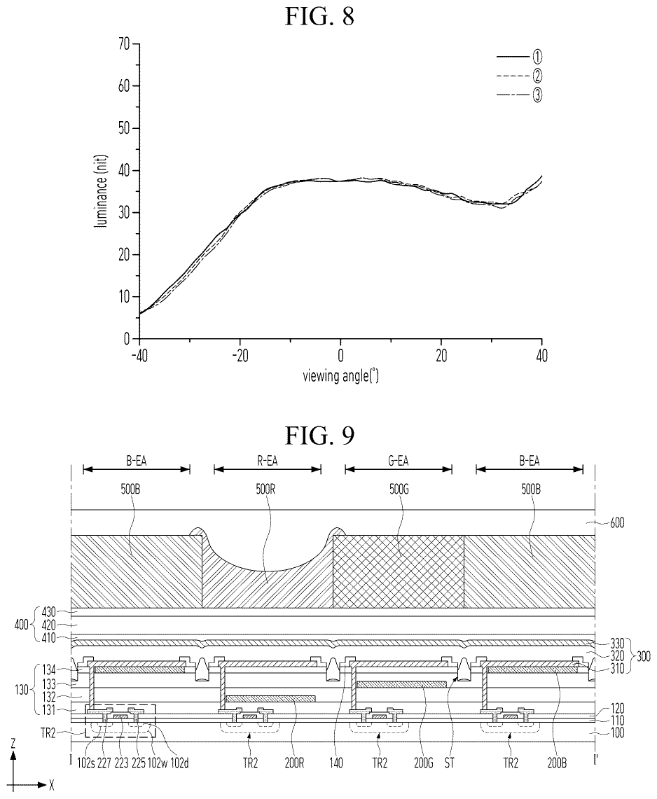

FIG. 8 is a graph showing the luminance of a first red color filter \textcircled{1} having a thicknesses of 1.3 [symbol] , a second red color filter \textcircled{2} having a thicknesses of 1.5 [symbol] and a third red color filter \textcircled{3} having a thicknesses of 2.0 [symbol] according to a viewing angle. Herein, the first red color filter, the second red color filter and the third red color filter include a red pigment.

Referring to FIG. 8, luminance of the red color recognized by viewers having a same viewing angle can be different according to a viewing direction. For example, a red color recognized by a viewer having a viewing angle of 30° to 40° to the right from the front can have different luminance from a red color recognized by a viewer having a viewing angle of 30° to 40° to the left from the front. The asymmetry in the luminance of the red color depending on a viewing direction can't be improved by varying a thickness of the red color filter having a red pigment. Thus, in the display apparatus according to the embodiments of the present disclosure, a thickness of the red color filter 500R overlapping with the red emission area R-EA can be minimized. For example, in the display apparatus according to the embodiments of the present disclosure, the thickness of the red color filter 500R can be 1.3 [symbol] . Therefore, in the display apparatus according to the embodiments of the present disclosure, the red color filter 500R can have a smaller thickness than the green color filter 500G and the blue color filter 500B.

Referring to FIGS. 4 and 5, in the display apparatus according to the embodiments of the present disclosure, the red color filter 500R can have a curved region CA toward the filter planarization layer 600. The curved region CA of the red color filter 500R can have a concave shape with respect to the center of the red color filter 500R. For example, a thickness of the red color filer 500R can decrease from an edge region disposed close to the green color filter 500G or the blue color filter 500B toward a central region including the center. The red color filter 500R can have a symmetrical shape with respect to the central region. For example, a portion of the curved region CA disposed close to the green color filter 500G can have a same curvature as a portion of the curved region CA disposed close to the blue color filter 500B.

The curved region CA of the red color filter 500R having a concave shape can be filled by the filter planarization layer 600. The filter planarization layer 600 can be in direct contact with the curved region CA of the red color filter 500R. For example, a thickness difference due to the curved region CA of the red color filter 500R can be removed by the filter planarization layer 600.

The filter planarization layer 600 can have a refractive index larger than the red color filer 500R. Thus, in the display apparatus according to the embodiments of the present disclosure, the light passing through the red color filter 500R can be converged by a difference in the refractive index between the red color filter 500R and the filter planarization layer 600. For example, in the display apparatus according to the embodiments of the present disclosure, the light L1 passing through the red color filter 500R and travelling toward the blue color filter 500B and the light L2 passing through the red color filter 500R and travelling toward the green color filter 500G can be refracted toward the inside of the red emission area R-EA at a boundary between the curved region CA and the filter planarization layer 600. For example, in the display apparatus according to the embodiments of the present disclosure, the boundary between the curved region CA of the red color filter 500R and the filter planarization layer 600 can function as a convex lens. Therefore, in the display apparatus according to the embodiments of the present disclosure, the luminance of the red light emitted from the red emission area R-EA can be improved. And, in the display apparatus according to the embodiments of the present disclosure, the overall luminance of the image recognized by the user can be improved.

Accordingly, the display apparatus according to the embodiments of the present disclosure can include the light-emitting devices 300 on the emission areas R-EA, G-EA and B-EA of the device substrate 100, the color filters 500R, 500G and 500B on the light-emitting devices 300, and the filter planarization layer 600 on the color filters 500R, 500G and 500B, wherein the red color filter 500R overlapping with the red emission area R-EA can have a smaller thickness than the green color filter 500G overlapping with the green emission area G-EA and the blue color filter 500B overlapping with the blue emission area B-EA, wherein the red color filter 500R can include the curved region CA being in contact with the filter planarization layer 600, and wherein the filter planarization layer 600 can have a refractive index larger than the red color filter 500R. Thus, in the display apparatus according to the embodiments of the present disclosure, the asymmetry in the luminance of the green color and the blue color depending on a viewing direction of the user can be prevented or reduced, and the luminance of the red light emitted from the red emission area R-EA can be improved. Therefore, in the display apparatus according to the embodiments of the present disclosure, the quality and the overall luminance of the image provided to the user can be improved. In the display apparatus according to the embodiments of the present disclosure, the low power operation can be possible and the power consumption can be reduced.

The display apparatus according to the embodiments of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third well region, a third drain region, a third source region, a third gate electrode, a third drain electrode and a third source region. The third well region, the third drain region and the third source region can be formed in the device substrate 100. The third gate electrode of each pixel area PA can be electrically connected to the gate line GL, the third drain electrode of each pixel area PA can be electrically connected to an initial line applying an initial signal, and the third source electrode of each pixel area PA can be electrically connected to the storage capacitor Cst of the corresponding pixel area PA. Thus, in the display apparatus according to another embodiment of the present disclosure, the degree of freedom in the configuration of each driving circuit DC can be improved.

In the display apparatus according to the embodiments of the present disclosure, the location and the electric connection of the first drain electrode, the first source electrode, the second drain electrodes 225 and the second source electrode 227 of each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiments of the present disclosure is described that the first well region, the second drain region 102d and the second source region 102s of each pixel area PA include a p-type impurity, and the first drain region, the first source region and the second well region 102w of each pixel area PA include an n-type impurity. However, in the display apparatus according to another embodiment of the present disclosure, the second well region 102w of each pixel area PA can include a same type conductive impurity as the first well region of the corresponding pixel area PA. For example, in the display apparatus according to another embodiment of the present disclosure, the first well region and the second well region 102w of each pixel area PA can include a p-type impurity, and the first drain region, the first source region, the second drain region 102d and the second source region 102s of each pixel area PA can include an n-type impurity. Thus, in the display apparatus according to another embodiment of the present disclosure, the degree of freedom in the configuration of each driving circuit DC and the type of each thin film transistor TR1 and TR2 can be improved.

The display apparatus according to the embodiments of the present disclosure is described as the device substrate 100 is a wafer formed of a semiconductor material, such as silicon. However, in the display apparatus according to another embodiment of the present disclosure, the device substrate 100 can include glass or plastic. In the display apparatus according to another embodiment of the present disclosure, the driving circuit DC of each pixel area PA can be formed on the upper surface of the device substrate 100. For example, in the display apparatus according to another embodiment of the present disclosure, a buffer insulating layer including an inorganic insulating material, such as silicon oxide (SiOx) and silicon nitride (SiNx) can be formed on the upper surface of the device substrate 100, and each of the first thin film transistor TR1 and the second thin film transistor TR2 in each pixel area PA can include a semiconductor pattern formed on the buffer insulating layer. The semiconductor pattern can include a semiconductor material. For example, a first semiconductor pattern of the first thin film transistor TR1 and a second semiconductor pattern of the second thin film transistor TR2 in each pixel area PA can include an oxide semiconductor, such as IGZO. Thus, in the display apparatus according to another embodiment of the present disclosure, the degree of freedom in the material of the device substrate 100 and the configuration of each driving circuit DC can be improved.

The display apparatus according to the embodiments of the present disclosure is described as each of the color filters 500R, 500G and 500B includes a pigment. However, in the display apparatus according to another embodiment of the present disclosure, at least one of the color filters 500R, 500G and 500B can be made of a different type material. For example, in the display apparatus according to another embodiment of the present disclosure, the blue color filter 500B can include a blue dye. Thus, in the display apparatus according to another embodiment of the present disclosure, the degree of freedom in the material of the color filters 500R, 500G and 500B can be improved.

The display apparatus according to the embodiments of the present disclosure is described that the red color filter 500R having a smaller thickness than the green color filer 500G and the blue color filter 500B includes the curved region CA. However, in the display apparatus according to another embodiment of the present disclosure, the green color filter 500G and/or the blue color filter 500B can have a relatively small thickness. Thus, in the display apparatus according to another embodiment of the present disclosure, each of the color filters 500R, 500G and 500B can include a lower surface toward the device substrate 100 and an upper surface opposite to the lower surface, an upper surface of the red color filter 500R can be parallel to a lower surface of the red color filter 500R, and an upper surface of the green color filter 500G and/or an upper surface of the blue color filter 500B can include the curved region CA. For example, in the display apparatus according to another embodiment of the present disclosure, the asymmetry in the luminance of at least one of the color filters 500R, 500G and 500B can be improved by increasing a thickness, and the luminance of the color filter 500R, 500G and 500B in which the asymmetry in the luminance is not improved by an increase of the thickness can be improved by using the curved region CA. Therefore, in the display apparatus according to another embodiment of the present disclosure, the quality of the image recognized by the user can be improved, regardless of the configuration of the color filters 500R, 500G and 500B.

The display apparatus according to the embodiments of the present disclosure is described that an edge region of the red color filter 500R can have a same thickness as the green color filter 500G and the blue color filter 500B. However, in the display apparatus according to another embodiment of the present disclosure, the maximum thickness of the red color filter 500R can be different from a thickness of the green color filter 500G and a thickness of the blue color filter 500B. For example, in the display apparatus according to another embodiment of the present disclosure, the upper surface of the green color filter 500G and the upper surface of the blue color filter 500B toward the filter planarization layer can be partially covered by the edge region of the red color filter, as shown in FIG. 9. An overlapping region of the red color filter 500R and the green color filter 500G and an overlapping area of the red color filter 500R and the blue color filter 500R can be disposed within the non-emission area. For example, the overlapping region of the red color filter 500R and the green color filter 500G and the overlapping area of the red color filter 500R and the blue color filter 500R can overlap the separating trench ST. Thus, in the display apparatus according to another embodiment of the present disclosure, the light passing through the red color filter 500R and travelling toward the blue color filter 500B or the green color filter 500G can be effectively converged. Therefore, in the display apparatus according to another embodiment of the present disclosure, the overall luminance of the image provided to the user can be effectively improved.

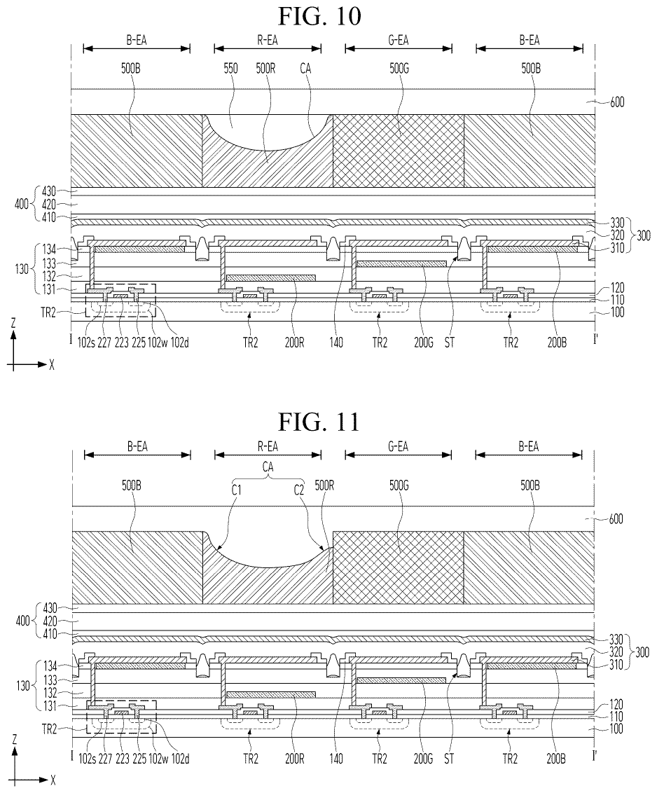

The display apparatus according to the embodiments of the present disclosure is described that the filter planarization layer 600 is in direct contact with the curved region CA of the red color filter 500R. However, in the display apparatus according to another embodiment of the present disclosure, the filter planarization layer 600 can be spaced apart from the curved region CA of the red color filter 500R. For example, in the display apparatus according to another embodiment of the present disclosure, an intermediate insulating layer 550 can be disposed between the curved region CA of the red color filter 500R and the filter planarization layer 600, as shown in FIG. 10. The intermediate insulating layer 550 can include an insulating material. The intermediate insulating layer 550 can fill the curved region CA of the red color filter 500R. For example, the intermediate insulating layer 550 can include an organic insulating material. An upper surface of the intermediate insulating layer 550 toward the filter planarization layer 600 can have a same level as the upper surface of the green color filter 500G and the upper surface of the blue color filter 500B. For example, the upper surface of the intermediate insulating layer 550 toward the filter planarization layer 600 can be continuous with the upper surface of the green color filter 500G and the upper surface of the blue color filter 500B.

A refractive index of the intermediate insulating layer 550 can be larger than a reflective index of the red color filter 500R. Thus, in the display apparatus according to another embodiment of the present disclosure, a boundary between the curved region CA of the red color filter 500R and the intermediate insulating layer 550 can function as a convex lens. Therefore, in the display apparatus according to the embodiments of the present disclosure, the light extraction efficiency of the red emission area R-EA can be improved, regardless of the material of the filter planarization layer 600. For example, in the display apparatus according to another embodiment of the present disclosure, the degree of freedom in the material of the filter planarization layer 600 can be improved.

The display apparatus according to the embodiments of the present disclosure is described as the red color filter 500R has a symmetrical shape with respect to the central region. However, in the display apparatus according to another embodiment of the present disclosure, the curved region CA of the red color filter 500R can have various shapes. For example, in the display apparatus according to another embodiment of the present disclosure, the curved region CA of the red color filter 500R can include a first curved surface C1 disposed close to the blue color filter 500B and a second curved surface C2 disposed close to the green color filter 500G, and the curvature of the second curved surface C2 can be different from the curvature of the first curved surface C1, as shown in FIG. 11. For example, a second edge region of the red color filter 500R overlapping with the second curved surface C2 can have a different thickness from a first edge region of the red color filter 500R overlapping with the first curved surface C1. The first curved surface C1 can have a concave shape toward a boundary between the red color filter 500R and the blue color filter 500B, and the second curved surface C2 can have a concave shape toward a boundary between the red color filter 500R and the green color filter 500G. A shape of the second curved surface C2 can be different from a shape of the first curved surface C1. Thus, in the display apparatus according to another embodiment of the present disclosure, the amount of the light converged by the first curved surface C1 can be different from the amount of the light converged by the second curved surface C2. Therefore, in the display apparatus according to another embodiment of the present disclosure, the asymmetry in the luminance of the red light passing through the red color filter 500R depending on a viewing direction can be reduced by using a shape of the curved region CA.

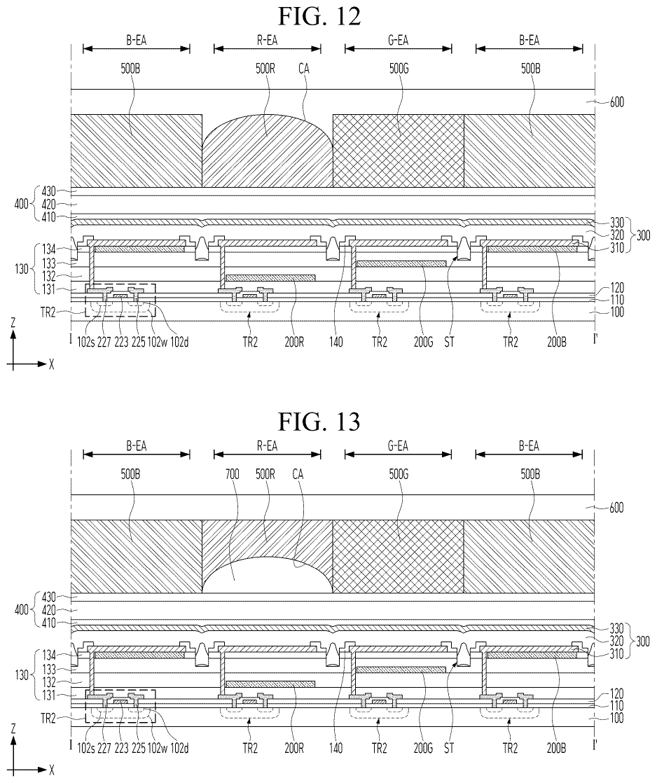

In the display apparatus according to another embodiment of the present disclosure, the curved region CA of the red color filter 500R can have a convex shape with respect to the center of the red color filter 500R, the filter planarization layer 600 contacting the curved region CA can have a refractive index smaller than the red color filter 500R, as shown in FIG. 12. In the display apparatus according to another embodiment of the present disclosure, a boundary between the curved region CA of the red color filter 500R and the filter planarization layer 600 can function as a convex lens due to the different in the refractive index. Therefore, in the display apparatus according to another embodiment of the present disclosure, the degree of freedom in the shape of the curved region CA can be improved.

The display apparatus according to the embodiments of the present disclosure is described that a surface of the red color filter 500R toward the filter planarization layer 600 is the curved region CA. However, in the display apparatus according to the embodiments of the present disclosure, an upper surface of the red color filter 500R toward the filter planarization layer 600 can be continuous with the upper surface of the green color filter 500G and the upper surface of the blue color filter 500B. For example, in the display apparatus according to another embodiment of the present disclosure, a collecting lens 700 can be disposed between the encapsulation structure 400 and the red color filter 500R, a surface of the collecting lens 700 opposite to the device substrate 100 can have a convex shape, and a lower surface of the red color filter 500R toward the device substrate 100 can be in direct contact with a surface of the collecting lens 700 having a convex shape, as shown in FIG. 13.

A lower surface of the collecting lens 700 toward the device substrate 100 can be in direct contact with the upper surface of the third encapsulating layer 430. For example, the lower surface of the collecting lens 700 can be continuous with the lower surface of the green color filter 500G and the lower surface of the blue color filter 500B. The collecting lens 700 can overlap the red emission area R-EA. The collecting lens 700 can't overlap the green emission area G-EA and the blue emission area B-EA. For example, the collecting lens 700 can be completely covered by the red color filter 500R.

The collecting lens 700 can include a transparent material. The collecting lens 700 can include an insulating material. The collecting lens 700 can include a polymer material. A refractive index of the collecting lens 700 can be larger than a refractive index of the red color filter 500R. In the display apparatus according to another embodiment of the present disclosure, a boundary between the collecting lens 700 and the red color filter 500R can function as a convex lens. Therefore, in the display apparatus according to another embodiment of the present disclosure, the degree of freedom in the location of the curved region CA can be improved.

In the display apparatus according to another embodiment of the present disclosure, the red color filter 500R on the collecting lens 700 can include a lower surface contacting the surface of the collecting lens 700 having a convex shape and a curved region having a concave shape and contacting the filter planarization layer 600. For example, in the display apparatus according to another embodiment of the present disclosure, a lower end portion and an upper end portion of the red color filter 500R can include a surface functioning as a convex lens. Thus, in the display apparatus according to another embodiment of the present disclosure, the light passing through the red color filter 500R can be effectively converged. Therefore, in the display apparatus according to another embodiment of the present disclosure, the asymmetric in the luminance depending on a viewing direction can be improved, and the overall luminance can be increased.

As a result, the display apparatus according to the embodiments of the present disclosure can comprise the light-emitting devices on the emission areas of the device substrate, the color filters on the light-emitting devices and the filter planarization layer on the color filters, wherein each of the light-emitting devices can display a same color as adjacent light-emitting device, wherein the color filters can include the first color filter and the second color filter made of a different material from the first color filter, and wherein at least one of the lower surface and the upper surface of the second color filter can include the curved region. Thus, in the display apparatus according to the embodiments of the present disclosure, the deviation in the luminance according to a direction in which the viewer at the same viewing angle views the image can be improved, and the overall luminance can be increased. Accordingly, in the display apparatus according to the embodiments of the present disclosure, the efficiency of each light-emitting device can be improved. In the display apparatus according to the embodiments of the present disclosure, the low power operation can be possible and the power consumption can be reduced.

What is claimed is:

1. A display apparatus comprising:
light-emitting devices on emission areas of a device substrate;
color filters on the light-emitting devices, the color filters overlapping with the emission areas; and
a filter planarization layer on the color filters, the filter planarization layer extending beyond each of the emission areas,
wherein the color filters include a first color filter and a second color filter including a different material from the first color filter,
wherein the second color filter includes a central region and a first edge region disposed between the central region and the first color filter, and
wherein a thickness of the second color filter gradually changes from the first edge region toward the central region of the second color filter.

2. The display apparatus according to claim 1, wherein a thickness of the central region of the second color filter is smaller than a thickness of the first edge region of the second color filter, and
wherein a thickness of the first color filter is same as the thickness of the first edge region of the second color filter.

3. The display apparatus according to claim 1, wherein an upper surface of the second color filter opposite to the device substrate includes a curved region connecting the central region and the first edge region of the second color filter, and
wherein the curved region of the second color filter has a concave shape toward a boundary between the first color filter and the second color filter.

4. The display apparatus according to claim 3, wherein the curved region of the second color filter is in contact with the filter planarization layer, and
wherein the filter planarization layer has a refractive index larger than the second color filter.

5. The display apparatus according to claim 1, wherein the color filters further include a third color filter including a different material from the first color filter and the second color filter,
wherein the second color filter is disposed between the first color filter and the third color filter,
wherein the second color filter further includes a second edge region disposed between the central region of the second color filter and the third color filter, and
wherein a thickness of the second color filter gradually changes toward the central region from the second edge region of the second color filter.

6. The display apparatus according to claim 5, wherein the second edge region of the second color filter has a shape symmetrical to the first edge region with respect to the central region of the second color filter.

7. The display apparatus according to claim 5, wherein the first color filter is a color filter including a blue pigment, the second color filter is a color filter including a red pigment, and the third color filter is a color filter including a green pigment.

8. The display apparatus according to claim 5, wherein the first edge region of the second color filter includes a portion overlapping with the first color filter, and the second edge region of the second color filter includes a portion overlapping with the third color filter.

9. The display apparatus according to claim 5, wherein each of the first color filter, the second color filter and the third color filter includes a lower surface toward the device substrate,
wherein a lower surface of the second color filter is disposed on a same layer as a lower surface of the first color filter and a lower surface of the third color filter, and
wherein a thickness of the third color filter is same as a thickness of the first color filter.

10. The display apparatus according to claim 9, wherein a thickness of the second edge region of the second color filter is different from a thickness of the first edge region of the second color filter.

11. The display apparatus according to claim 1, wherein an intermediate insulating layer is disposed between an upper surface of the second color filter and the filter planarization layer, and
wherein the intermediate insulating layer has a refractive index larger than the second color filter.

12. The display apparatus according to claim 1, further comprising a collecting lens between the light-emitting device and the second color filter,
wherein a surface of the collecting lens toward the filter planarization layer has a convex shape, and
wherein the second color filter has a refractive index smaller than the collecting lens.

13. A display apparatus, comprising:
a device substrate including a first emission area and a second emission area for providing a different color from the first emission area;
a first light-emitting device on the first emission area of the device substrate, the first light-emitting device having a stacked structure composed of a first lower electrode, a first light-emitting unit and a first upper electrode;
a second light-emitting device on the second emission area of the device substrate, the second light-emitting device having a stacked structure composed of a second lower electrode, a second light-emitting unit and a second upper electrode;
a first color filter on the first light-emitting device, the first color filter overlapping with the first emission area;
a second color filter on the second light-emitting device, the second color filter overlapping with the second emission area; and
a filter planarization layer on the first color filter and the second color filter,
wherein light generated by the second light-emitting unit displays a same color as light generated by the first light-emitting unit,
wherein each of the first color filter and the second color filter includes a lower surface toward the device substrate and an upper surface toward the filter planarization layer, and
wherein at least one of the lower surface and the upper surface of the second color filter has a concave shape toward a center portion of the second color filter.

14. The display apparatus according to claim 13, wherein the upper surface of the first color filter has a shape parallel to the lower surface of the first color filter.

15. The display apparatus according to claim 13, further comprising a collecting lens between the second light-emitting device and the second color filter,
wherein the collecting lens overlaps the second emission area,
wherein an end portion of the collecting lens is disposed outside the first emission area, and
wherein a surface of the collecting lens toward the filter planarization layer has a convex shape.

16. The display apparatus according to claim 15, wherein the lower surface of the second color filter is in contact with the surface of the collecting lens toward the filter planarization layer.

17. The display apparatus according to claim 15, wherein the second color filter has a refractive index smaller than the collecting lens.

18. The display apparatus according to claim 17, wherein the upper surface of the second color filer is continuous with the upper surface of the first color filter.

19. The display apparatus according to claim 15, further comprising an encapsulation structure between the first light-emitting device and the first color filter, the encapsulation structure extending between the second light-emitting device and the second color filter,
wherein a lower surface of the collecting lens and the lower surface of the first color filter toward the device substrate are in contact with an upper surface of the encapsulation structure toward the filter planarization layer.

20. The display apparatus according to claim 13, further comprising an encapsulation structure between the first light-emitting device and the first color filter, the encapsulation structure extending between the second light-emitting device and the second color filter.
